(19) United States
(12) Patent Application Publication
(10) Pub. No.: US 2024/0096186 A1
(43) Pub. Date: Mar. 21, 2024

(54) METHODS AND APPARATUSES FOR DETERMINING TAG INFORMATION

(71) Applicant: Sensormatic Electronics, LLC, Boca Raton, FL (US)

(72) Inventors: Hubert A. PATTERSON, Boca Raton, FL (US); Adam S. BERGMAN, Boca Raton, FL (US); Steve E. TRIVELPIECE, Boca Raton, FL (US)

(21) Appl. No.: 18/266,226

(22) PCT Filed: Dec. 2, 2021
(86) PCT No.: PCT/US2021/072686

§ 371 Date: Jun. 8, 2023

Related U.S. Application Data
(60) Provisional application No. 63/122,642, filed on Dec. 8, 2020.

(51) Int. Cl. G08B 13/24; G01D 5/14; G06K 19/06; G08B 27/00

(52) U.S. Cl. CPC G08B 13/2448; G01D 5/14; G06K 19/06187; G08B 27/00

(57) ABSTRACT

Aspects of the present disclosure include methods, systems, and non-transitory computer readable media for receiving a plurality of reception magnetic signals, determining state information associated with each marker of the plurality of markers based on a corresponding transmission magnetic signal of the plurality of transmission magnetic signals and a corresponding reception magnetic signal of the plurality of reception magnetic signals, and determining tag information based on the state information of the plurality of markers.

### CROSS-REFERENCE TO RELATED APPLICATION

This application claims priority to U.S. Application No. 63/122,642, entitled “METHODS AND APPARATUSES FOR DETERMINING TAG INFORMATION,” filed on Dec. 8, 2020, the disclosure of which is incorporated by reference herein in its entirety.

### BACKGROUND

A retail store may encounter loss due to theft, fraud, or mistakes. For example, a would-be thief may remove a merchandize item from the retail store without proper payment. Additionally, store employees cause loss due to operational errors (e.g., misplace merchandize items during restocking or shelfing), theft, “sweethearting” (offering discounted or free merchandize items to friends or family), and/or damage. While a retail store may employ security personnel, surveillance, and/or analytical methods to minimize loss, it may be desirable to rely on other countermeasures for loss prevention.

### SUMMARY

This summary is provided to introduce a selection of concepts in a simplified form that are further described below in the DETAILED DESCRIPTION. This summary is not intended to identify key features of the claimed subject matter, nor is it intended to be used as an aid in determining the scope of the claimed subject matter.

Aspects of the present disclosure include methods for receiving a plurality of reception magnetic signals, wherein: each one of the plurality of reception magnetic signals is based on at least a portion of a corresponding transmission magnetic signal of a plurality of transmission magnetic signals passing through a corresponding magnetic material of a plurality of magnetic materials associated with a plurality of markers of a security tag associated with a merchandize item, each of the plurality of transmission magnetic signals is transmitted at a frequency of a plurality of frequencies, each of the plurality of magnetic materials is configured to have a first absorption coefficient for a corresponding transmission magnetic signal of the plurality of transmission magnetic signals and a second absorption coefficient for the corresponding transmission magnetic signal of the plurality of transmission magnetic signals, determining state information associated with each marker of the plurality of markers based on a corresponding transmission magnetic signal of the plurality of transmission magnetic signals and a corresponding reception magnetic signal of the plurality of reception magnetic signals, and determining tag information based on the state information of the plurality of markers.

Aspects of the present disclosure includes a magnetic signal receiver configured to receive a plurality of reception magnetic signals, wherein: each of the plurality of reception magnetic signals is based on at least a portion of a corresponding transmission magnetic signal of a plurality of transmission magnetic signals passing through a corresponding magnetic material of a plurality of magnetic materials associated with a plurality of markers of a security tag associated with a merchandize item, each of the plurality of transmission magnetic signals is transmitted at a frequency of a plurality of frequencies, each one of the plurality of magnetic materials is configured to have a first absorption coefficient for a corresponding transmission magnetic signal of the plurality of transmission magnetic signals and a second absorption coefficient for the corresponding transmission magnetic signal of the plurality of transmission magnetic signals, determine state information associated with each marker of the plurality of markers based on a corresponding transmission magnetic signal of the plurality of transmission magnetic signals and a corresponding reception magnetic signal of the plurality of reception magnetic signals, and determine tag information based on the state information of the plurality of markers.

Aspects of the present disclosure include a non-transitory computer readable medium having instructions that, when executed by a processor, cause the processor to receive a plurality of reception magnetic signals, wherein: each of the plurality of reception magnetic signals is based on at least a portion of a corresponding transmission magnetic signal of a plurality of transmission magnetic signals passing through a corresponding magnetic material of a plurality of magnetic materials associated with a plurality of markers of a security tag associated with a merchandize item, each of the plurality of transmission magnetic signals is transmitted at a frequency of a plurality of frequencies, each one of the plurality of magnetic materials is configured to have a first absorption coefficient for a corresponding transmission magnetic signal of the plurality of transmission magnetic signals and a second absorption coefficient for the corresponding transmission magnetic signal of the plurality of transmission magnetic signals, determine state information associated with each marker of the plurality of markers based on a corresponding transmission magnetic signal of the plurality of transmission magnetic signals and a corresponding reception magnetic signal of the plurality of reception magnetic signals, and determine tag information based on the state information of the plurality of markers.

### BRIEF DESCRIPTION OF THE DRAWINGS

The features believed to be characteristic of aspects of the disclosure are set forth in the appended claims. In the description that follows, like parts are marked throughout the specification and drawings with the same numerals, respectively. The drawing figures are not necessarily drawn to scale and certain figures may be shown in exaggerated or generalized form in the interest of clarity and conciseness. The disclosure itself, however, as well as a preferred mode of use, further objects and advantages thereof, will be best understood by reference to the following detailed description of illustrative aspects of the disclosure when read in conjunction with the accompanying drawings, wherein:

FIG. 1 illustrates an example of an environment for determining tag information in accordance with aspects of the present disclosure:

FIG. 2 illustrates an example of a method for determining tag information in accordance with aspects of the present disclosure; and

FIG. 3 illustrates an example of a computer system in accordance with aspects of the present disclosure.

### DETAILED DESCRIPTION

The following includes definitions of selected terms employed herein. The definitions include various examples and/or forms of components that fall within the scope of a term and that may be used for implementation. The examples are not intended to be limiting.

An aspect of the present disclosure may use Nuclear Quadrature (or Quadrupole) Resonance (NQR) in an electronic article surveillance (EAS) retail anti-theft system. By using a marker containing material with NQR properties, the marker may be attached to a security tag (e.g., an EAS tag), a swing label, or directly on an article of sale. The EAS system may detect the specific resonance pattern of the NQR material. In an implementation, the NQR marker may include an NQR material combined with a magnet or other NQR materials to create desired resonance signatures. Some aspects of the present disclosure may include methods of modifying or disarming NQR marker at point of sale (POS) by altering the resonance signature (e.g., frequency) of the marker by means of heat, crystallization, chemical reaction, magnetization, or demagnetization.

In certain implementations, a security tag may include two NQR markers: a permanently attached NQR marker with a first resonance signature and a removable NQR marker (on an EAS tag) with a second resonance signature. Various methods described of detecting item sold/stolen, depending on whether one or both markers are detected, or whether any modification/disarming (made at the POS) of the signature of one of the markers (e.g., tampering with the markers to prevent detections). In some examples, the EAS system may use NQR signatures to identify a type of product or encode unique serial numbers for products.

In one instance, the NQR markers may be printed, attached, or sewn onto the article or the article label (e.g., garment label).

In certain variations, the EAS system may use higher-frequency NQR markers to determine if an article is close to the body by measuring frequency response, comparing to known frequency response in air, and calculating expected frequency shift.

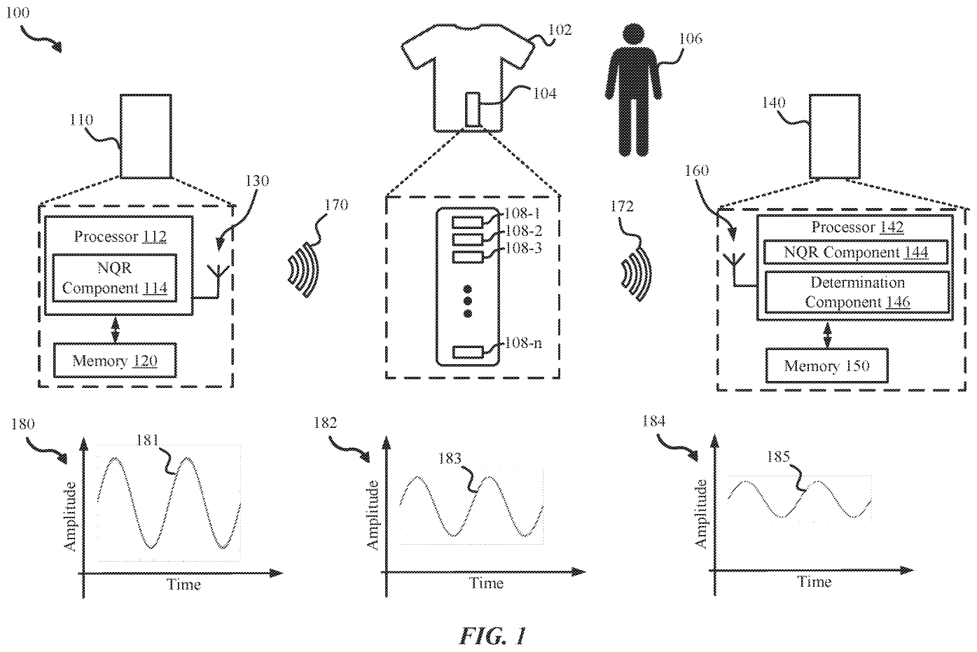

Referring to FIG. 1, in a non-limiting implementation, an example of an environment 100 (e.g., a retail store) may include a person 106 attempting to purchase a merchandize item 102 having a security tag 104. The security tag 104 may be removably coupled to the merchandize item 102 (e.g., locked). The security tag 104 may include a plurality of markers 108-1, 108-2 . . . 108-n, where n is an integer greater than 2. The plurality of markers 108-1, 108-2 . . . 108-n may include different magnetic materials each having a different NQR frequency. For example, the marker 108-1 may include a first magnetic material having a first NQR frequency f₁, the marker 108-2 may include a second magnetic material having a second NQR frequency f₂ . . . and so on.

In certain implementations, the environment 100 may include a magnetic signal transmitter 110 and a magnetic signal receiver 140. The magnetic signal transmitter 110 may be configured to transmit one or more transmission magnetic signals 170. The one or more transmission magnetic signals 170 may include one or more frequencies or frequency ranges. The magnetic signal receiver 140 may be configured to receive one or more reception magnetic signals 172. The one or more reception magnetic signals 172 may include one or more frequencies or frequency ranges.

In an implementation, the magnetic signal transmitter 110 may include a processor 112 and a memory 120. The processor 112 may include a NQR component 114 configured to transmit the one or more transmission magnetic signals 170 via a transmitter antenna 130. The magnetic signal transmitter 110 may include the transmitter antenna 130. The transmitter antenna 130 may be a dipole antenna, a radio frequency (RF) antenna, a coil, or other suitable devices for transmitting magnetic signals. The NQR component 114 may be implemented as hardware, software, or a combination thereof.

In an implementation, the magnetic signal receiver 140 may include a processor 142 and a memory 150. The processor 142 may include a NQR component 144 configured to receive the one or more reception magnetic signals 172 via a receiver antenna 160. The magnetic signal receiver 140 may include the receiver antenna 160. The receiver antenna 160 may be a dipole antenna, a RF antenna, a coil, or other suitable devices for receiving magnetic signals. The processor 142 may include a determination component 146 configured to determine tag information associated with the security tag 104 based on the one or more reception magnetic signals 172 received. The NQR component 144 and/or the determination component 146 may be implemented as hardware, software, or a combination thereof.

In some instances, a first graph 180 may show a first waveform 181 of the one or more transmission magnetic signals 170. A second graph 182 may show a second waveform 183 of the one or more reception magnetic signals 172 when the magnetic materials of one or more of the plurality of markers 108-1, 108-2 . . . 108-n are configured to have a first absorption coefficient. A third graph 184 may show a third waveform 185 of the one or more reception magnetic signals 172 when the magnetic materials of one or more of the plurality of markers 108-1, 108-2 . . . 108-n are configured to have a second absorption coefficient. The absorption coefficients of the magnetic materials in the plurality of markers 108-1, 108-2 . . . 108-n may be adjusted to encode tag information, as discussed in detail below.

The term “processor.” as used herein, can refer to a device that processes signals and performs general computing and arithmetic functions. Signals processed by the processor can include digital signals, data signals, computer instructions, processor instructions, messages, a bit, a bit stream, or other computing that can be received, transmitted and/or detected. A processor, for example, can include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described herein. The term “memory,” as used herein, can include volatile memory and/or nonvolatile memory. Non-volatile memory can include, for example, ROM (read only memory), PROM (programmable read only memory). EPROM (erasable PROM) and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDR SDRAM), and direct RAM bus RAM (DRRAM).

The term “memory,” as used herein, can include volatile memory and/or nonvolatile memory. Non-volatile memory can include, for example, ROM (read only memory), PROM (programmable read only memory), EPROM (erasable PROM) and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDR SDRAM), and direct RAM bus RAM (DRRAM).

During operation, the security tag 104 may be encoded with the tag information. The plurality of markers 108-1, 108-2 . . . 108-n may represent n bits of tag information. Each marker of the plurality of markers 108-1, 108-2 . . . 108-n may be “programmed” to a first state representing a first value or a second state representing a second value. The first state may be associated with a first absorption coefficient of the marker and the second state may be associated with a second absorption coefficient, different than the first absorption coefficient, of the marker. An external device (not shown) may change the state of each marker of the plurality of markers 108-1, 108-2 . . . 108-n by heat, crystallization, chemical reaction, magnetization, demagnetization, or other means.

When a marker of the plurality of markers 108-1, 108-2 . . . 108-n is in a first state, the marker may absorb a first portion of the one or more transmission magnetic signals 170 at a corresponding frequency (associated with the specific marker). When the marker is in a second state, the marker may absorb a second portion of the one or more transmission magnetic signals 170 at the corresponding frequency (associated with the specific marker). The absorption coefficient may be correlated with the amount of absorption by the marker.

In some implementations, the processor 112, the NQR component 114, and/or the transmitter antenna 130 of the magnetic signal transmitter 110 may transmit the one or more transmission magnetic signals 170. The one or more transmission magnetic signals 170 may include magnetic signals having more than one frequency. In some instances, the frequencies and/or frequency range may include the NQR frequencies associated with the magnetic materials in the plurality of markers 108-1, 108-2 . . . 108-n. For example, the one or more transmission magnetic signals 170 may include magnetic signals having the frequencies f₁, f₂ . . . fₙ. In another example, the one or more transmission magnetic signals 170 may include magnetic signals in a frequency range that includes the frequencies f₁, f₂ . . . fₙ.

In certain implementations, each transmission magnetic signal of the one or more transmission magnetic signals 170 may have a corresponding frequency. The transmission magnetic signal may have the first waveform 181 when transmitted by the magnetic signal transmitter 110. As the transmission magnetic signal propagates toward the magnetic signal receiver 140, a portion of the transmission magnetic signal may be absorbed by the ambient, the plurality of markers 108-1, 108-2 . . . 108-n, or other objects (not shown) in the environment 100. A corresponding reception magnetic signal of the one or more reception magnetic signals 172, to be received by the magnetic signal receiver 140, may have a waveform different than the first waveform 181 (e.g., the second waveform 183 or the third waveform 185), depending on the absorption coefficient of the corresponding marker of the plurality of markers 108-1, 108-2 . . . 108-n. If the corresponding marker has the first absorption coefficient (lower than the second absorption coefficient), the corresponding reception magnetic signal may have the second waveform 183. If the corresponding marker has the second absorption coefficient (higher than the first absorption coefficient), the corresponding reception magnetic signal may have the third waveform 185.

In some instances, the processor 142, the NQR component 144, the memory 150, and/or the receiver antenna 160 may receive the corresponding reception magnetic signal of the one or more reception magnetic signals 172.

In an implementation, the processor 142, the determination component 146, and/or the memory 150 may determine the state information of the corresponding marker (or the magnetic material of the corresponding marker). The state information may be indicated by the absorption coefficient of the corresponding marker. If the corresponding marker has the first absorption coefficient, the corresponding marker may be in the first state. If the corresponding marker has the second absorption coefficient, the corresponding marker may be in the second state. The processor 142, the determination component 146, and/or the memory 150 may determine the absorption coefficient of the corresponding marker based on the waveform 183, 185 (e.g., amplitude of the waveform 183, 185) of the corresponding reception magnetic signal of the one or more reception magnetic signals 172 received. Based on the waveform 183, 185, the processor 142, the determination component 146, and/or the memory 150 may determine the absorption coefficient of the corresponding reception magnetic signal. Based on the absorption coefficient of the corresponding reception magnetic signal, the processor 142, the determination component 146, and/or the memory 150 may determine the state information of the magnetic material of the corresponding marker.

In some implementations, the processor 142, the determination component 146, and/or the memory 150 may determine the tag information of the security tag 104 based on the state information of the plurality of markers 108-1, 108-2 . . . 108-n.

In an aspect, the tag information may indicate an identification string associated with the merchandize item 102, whether the merchandize item 102 has been sold, or other information (size, color, materials, etc. of the merchandize item 102) associated with the merchandize item 102.

In a first non-limiting example according to aspects of the present disclosure, the security tag 104 may include 4 markers (e.g., 108-1, 108-2, 108-3, 108-4). The 4 markers may each have a NQR frequency (e.g., f₁, f₂, f₃, f₄). The external device (not shown) may “program” the 4 markers so that the first marker 108-1 is in the first state (the first magnetic material of the first marker 108-1 has the first absorption), the second marker 108-2 is in the first state (the second magnetic material of the second marker 108-2 has the first absorption), the third marker 108-3 is in the second state (the third magnetic material of the third marker 108-3 has the second absorption), and the fourth marker 108-4 is in the second state (the fourth magnetic material of the fourth marker 108-4 has the second absorption). The first state may indicate a bit value of “0” and the second state may indicate a bit value of “1”. Therefore, the security tag 104 may have the tag information of 0011. The first absorption coefficient may be lower than the second absorption coefficient. The first marker 108-1 (in the first state or having a bit value of “0”) may indicate that the merchandize item 102 has been properly purchased by the person 106. The second, third, and fourth markers 108-2, 108-3, 108-4 may indicate a stock-keeping unit (SKU) number of the merchandize item 102 (i.e., 001).

In some aspects, the processor 112, the NQR component 114, the memory 120, and/or the transmission antenna 130 of the magnetic signal transmitter 110 may transmit the one or more transmission magnetic signals 170. The magnetic signal transmitter 110 may transmit the one or more transmission magnetic signals 170 upon detecting the security tag 104 passing between the magnetic signal transmitter 110 and the magnetic signal receiver 140 near an exit of a retail store. The magnetic signal transmitter 110 may transmit the one or more transmission magnetic signals 170 upon detecting the person 106 passing between the magnetic signal transmitter 110 and the magnetic signal receiver 140.

In one aspect, the processor 142, the NQR component 144, the memory 150, and/or the receiver antenna 160 of the magnetic signal receiver 140 may receive the one or more reception magnetic signals 172. The one or more reception magnetic signals 172 may include a first reception magnetic signal (with frequency of f₁) and a second reception magnetic signal (with frequency of f₂) having the second waveform 183 because the magnetic materials of the first marker 108-1 and the second marker 108-2 have the first absorption, and a third reception magnetic signal (with frequency of f₃) and a fourth reception magnetic signal (with frequency of f₄) having the third waveform 185 because the magnetic materials of the third marker 108-3 and the fourth marker 108-4 have the second absorption.

In certain aspects of the present disclosure, based on the received one or more reception magnetic signals 172, the processor 142, the determination component 146, the memory 150, and/or the receiver antenna 160 of the magnetic signal receiver 140 may determine the state information of the plurality of markers 108-1, 108-2 . . . 108-4. For example, the processor 142, the NQR component 144, the memory 150, and/or the receiver antenna 160 of the magnetic signal receiver 140 may determine that the first marker 108-1 and the second marker 108-2 are in the first state, and the third marker 108-3 and the fourth marker 108-4 are in the second state.

In one aspect, the processor 142, the determination component 146, the memory 150, and/or the receiver antenna 160 of the magnetic signal receiver 140 may determine tag information of the security tag based on the state information. For example, the processor 142, the NQR component 144, the memory 150, and/or the receiver antenna 160 of the magnetic signal receiver 140 may determine that the plurality of markers 108-1, 108-2 . . . 108-4 indicate a value of 0011.

In optional implementations, the magnetic signal receiver 140 may determine that the person 106 properly purchased the merchandize item 102 based on the tag information, and refrain from transmitting an indication signal to activate an alarm and/or notify a security personnel (not shown).

In a second non-limiting example according to aspects of the present disclosure, the security tag 104 may include 3 markers (e.g., 108-1, 108-2, 108-3). The 3 markers may each have a NQR frequency (e.g., f₁, f₂, f₃). The external device (not shown) may “program” the 3 markers so that the first marker 108-1 is in the second state (the first magnetic material of the first marker 108-1 has the second absorption), the second marker 108-2 is in the first state (the second magnetic material of the second marker 108-2 has the first absorption), and the third marker 108-3 is in the second state (the third magnetic material of the third marker 108-3 has the second absorption). The first state may indicate a bit value of “1” and the second state may indicate a bit value of “0”. Therefore, the security tag 104 may have the tag information of 010. The first absorption coefficient may be lower than the second absorption coefficient. The first marker 108-1 (in the second state or having a bit value of “0”) may indicate that the merchandize item 102 has not been properly purchased. The second and third markers 108-2, 108-3 may indicate a merchandize type of the merchandize item 102 (i.e., 10).

In some aspects, the processor 112, the NQR component 114, the memory 120, and/or the transmission antenna 130 of the magnetic signal transmitter 110 may transmit the one or more transmission magnetic signals 170. The magnetic signal transmitter 110 may transmit the one or more transmission magnetic signals 170 upon detecting the security tag 104 passing between the magnetic signal transmitter 110 and the magnetic signal receiver 140. The magnetic signal transmitter 110 may transmit the one or more transmission magnetic signals 170 upon detecting the person 106 passing between the magnetic signal transmitter 110 and the magnetic signal receiver 140.

In one aspect, the processor 142, the NQR component 144, the memory 150, and/or the receiver antenna 160 of the magnetic signal receiver 140 may receive the one or more reception magnetic signals 172. The one or more reception magnetic signals 172 may include a first reception magnetic signal (with frequency of f₁) and a third reception magnetic signal (with frequency of f₃) having the third waveform 185 because the magnetic materials of the first marker 108-1 and the third marker 108-3 have the second absorption, and a second reception magnetic signal (with frequency of f₂) having the second waveform 183 because the magnetic material of the second marker 108-2 has the first absorption.

In certain aspects of the present disclosure, based on the received one or more reception magnetic signals 172, the processor 142, the determination component 146, the memory 150, and/or the receiver antenna 160 of the magnetic signal receiver 140 may determine the state information of the plurality of markers 108-1, 108-2, 108-3. For example, the processor 142, the NQR component 144, the memory 150, and/or the receiver antenna 160 of the magnetic signal receiver 140 may determine that the first marker 108-1 and the third marker 108-3 are in the second state, and the second marker 108-2 is in the first state.

In one aspect, the processor 142, the determination component 146, the memory 150, and/or the receiver antenna 160 of the magnetic signal receiver 140 may determine tag information of the security tag based on the state information. For example, the processor 142, the NQR component 144, the memory 150, and/or the receiver antenna 160 of the magnetic signal receiver 140 may determine that the plurality of markers 108-1, 108-2, 108-3 indicate a value of 010.

In optional implementations, the magnetic signal receiver 140 may determine that the merchandize item 102 has not been properly purchased based on the tag information, and may transmit an indication signal to activate an alarm and/or notify a security personnel (not shown).

In some implementations, each of the plurality of markers 108-1, 108-2 . . . 108-n may include different magnetic materials (e.g., different in composition, size, crystallinity, phase, magnetic moment, etc.). The first and second absorption coefficients of a magnetic material may be different than the first and second absorption coefficients of a different magnetic material.

In an alternative implementation, the plurality of markers 108-1, 108-2 . . . 108-n may be printed, sewn, coupled, attached, or fastened to the merchandize item 102. In some implementations, the processor 142, the determination component 146, the memory 150, and/or the receiver antenna 160 of the magnetic signal receiver 140 may determine, based on the one or more reception magnetic signals 172, whether the plurality of markers 108-1, 108-2 . . . 108-n and/or the security tag 104 is placed close to (e.g., <1 centimeter (cm), 2 cm, or 3 cm) and/or within a threshold distance (e.g., <0.5 cm) of a body of the person 106 (e.g., worn by the person 106). The processor 142, the determination component 146, the memory 150, and/or the receiver antenna 160 of the magnetic signal receiver 140 may make the determination by comparing the frequency response of the plurality of markers 108-1, 108-2 . . . 108-n when close to the person 106 and a threshold frequency response associated with the security tag 104 being disposed at a distance larger than the threshold distance from an object. Specifically, the processor 142, the determination component 146, the memory 150, and/or the receiver antenna 160 of the magnetic signal receiver 140 may make the determination by examining the frequency shift (e.g., a deviation between the frequency response and the threshold frequency response is larger than a threshold deviation). Examples of the threshold deviation may be 2%, 5%, 10%, etc.

Examples of the magnetic materials may include NQR materials including hydrogen, carbon, nitrogen, chlorine, potassium, bromine, rubidium, iodine, cesium, or lead. In some implementations, the magnetic materials may include one or more NQR materials, or a combination of NQR materials and magnetic or non-magnetic materials.

In some instances, the tag information may include one or more of merchandize information, price, or purchase status associated with the merchandize item.

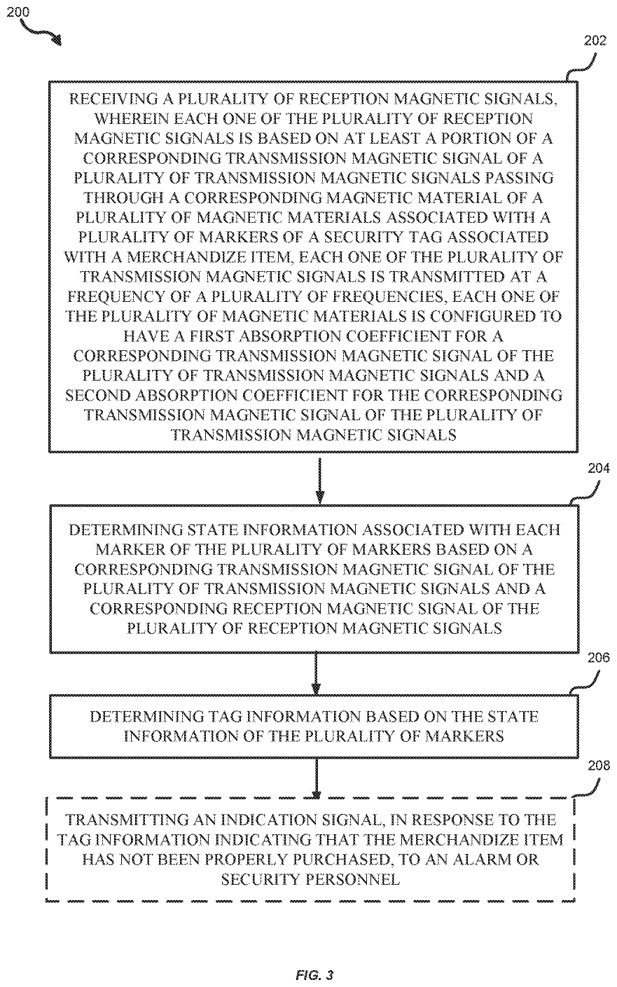

Turning to FIG. 2, an example of a method 200 for determining tag information by a magnetic signal receiver. Specifically, the method 200 may be performed by one or more of the processor 142, the NQR component 144, the determination component 146, the memory 150, and/or the receiver antenna 160 of the magnetic signal receiver 140.

At block 202, the method 200 may receive a plurality of reception magnetic signals, wherein each one of the plurality of reception magnetic signals is based on at least a portion of a corresponding transmission magnetic signal of a plurality of transmission magnetic signals passing through a corresponding magnetic material of a plurality of magnetic materials associated with a plurality of markers of a security tag associated with a merchandize item, each one of the plurality of transmission magnetic signals is transmitted at a frequency of a plurality of frequencies, each one of the plurality of magnetic materials is configured to have a first absorption coefficient for a corresponding transmission magnetic signal of the plurality of transmission magnetic signals and a second absorption coefficient for the corresponding transmission magnetic signal of the plurality of transmission magnetic signals. For example, the processor 142, the NQR component 144, the memory 150, and/or the receiver antenna 160 of the magnetic signal receiver 140 may receive a plurality of reception magnetic signals as described above. The processor 142, the NQR component 144, the memory 150, and/or the receiver antenna 160 of the magnetic signal receiver 140 may be configured to and/or define means for receiving a plurality of reception magnetic signals.

At block 204, the method 200 may determine state information associated with each marker of the plurality of markers based on a corresponding transmission magnetic signal of the plurality of transmission magnetic signals and a corresponding reception magnetic signal of the plurality of reception magnetic signals. For example, the processor 142, the determination component 146, the memory 150, and/or the receiver antenna 160 of the magnetic signal receiver 140 may determine state information associated with each marker of the plurality of markers as described above. The processor 142, the determination component 146, the memory 150, and/or the receiver antenna 160 of the magnetic signal receiver 140 may be configured to and/or define means for determining state information associated with each marker of the plurality of markers based on a corresponding transmission magnetic signal of the plurality of transmission magnetic signals and a corresponding reception magnetic signal of the plurality of reception magnetic signals.

At block 206, the method 200 may determine tag information based on the state information of the plurality of markers. For example, the processor 142, the determination component 146, the memory 150, and/or the receiver antenna 160 of the magnetic signal receiver 140 may determine tag information as described above. The processor 142, the determination component 146, the memory 150, and/or the receiver antenna 160 of the magnetic signal receiver 140 may be configured to and/or define means for determining tag information based on the state information of the plurality of markers.

In some implementations, the tag information may be used to determine whether the merchandize item 102 has been purchased. The tag information may include information associated with the merchandize item 102.

At block 208, the method 200 may optionally transmit an indication signal, in response to the tag information indicating that the merchandize item has not been properly purchased, to an alarm or security personnel.

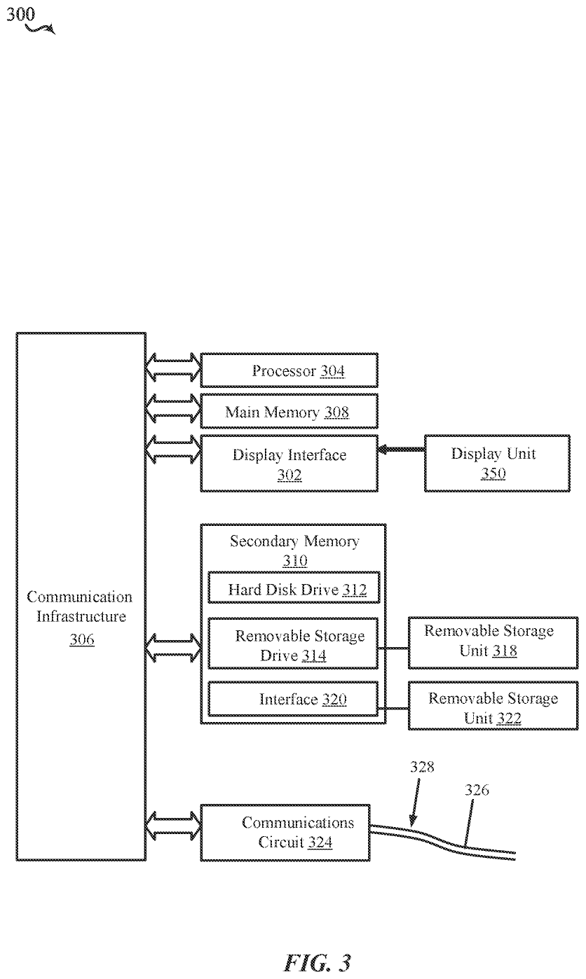

Aspects of the present disclosures may be implemented using hardware, software, or a combination thereof and may be implemented in one or more computer systems or other processing systems. In an aspect of the present disclosures, features are directed toward one or more computer systems capable of carrying out the functionality described herein. An example of such the computer system 300 is shown in FIG. 3. In some examples, the magnetic signal transmitter 110 and/or the magnetic signal receiver 140 may be implemented as the computer system 300 shown in FIG. 3. The magnetic signal transmitter 110 and/or the magnetic signal receiver 140 may include some or all of the components of the computer system 300.

The computer system 300 includes one or more processors, such as processor 304. The processor 304 is connected with a communication infrastructure 306 (e.g., a communications bus, cross-over bar, or network). Various software aspects are described in terms of this example computer system. After reading this description, it will become apparent to a person skilled in the relevant art(s) how to implement aspects of the disclosures using other computer systems and/or architectures.

The computer system 300 may include a display interface 302 that forwards graphics, text, and other data from the communication infrastructure 306 (or from a frame buffer not shown) for display on a display unit 350. Computer system 300 also includes a main memory 308, preferably random access memory (RAM), and may also include a secondary memory 310. The secondary memory 310 may include, for example, a hard disk drive 312, and/or a removable storage drive 314, representing a floppy disk drive, a magnetic tape drive, an optical disk drive, a universal serial bus (USB) flash drive, etc. The removable storage drive 314 reads from and/or writes to a removable storage unit 318 in a well-known manner. Removable storage unit 318 represents a floppy disk, magnetic tape, optical disk, USB flash drive etc., which is read by and written to removable storage drive 314. As will be appreciated, the removable storage unit 318 includes a computer usable storage medium having stored therein computer software and/or data. In some examples, one or more of the main memory 308, the secondary memory 310, the removable storage unit 318, and/or the removable storage unit 322 may be a non-transitory memory.

Alternative aspects of the present disclosures may include secondary memory 310 and may include other similar devices for allowing computer programs or other instructions to be loaded into computer system 300. Such devices may include, for example, a removable storage unit 322 and an interface 320. Examples of such may include a program cartridge and cartridge interface (such as that found in video game devices), a removable memory chip (such as an erasable programmable read only memory (EPROM), or programmable read only memory (PROM)) and associated socket, and the removable storage unit 322 and the interface 320, which allow software and data to be transferred from the removable storage unit 322 to computer system 300.

Computer system 300 may also include a communications circuit 324. The communications circuit 324 may allow software and data to be transferred between computer system 300 and external devices. Examples of the communications circuit 324 may include a modem, a network interface (such as an Ethernet card), a communications port, a Personal Computer Memory Card International Association (PCMCIA) slot and card, etc. Software and data transferred via the communications circuit 324 are in the form of signals 328, which may be electronic, electromagnetic, optical or other signals capable of being received by the communications circuit 324. These signals 328 are provided to the communications circuit 324 via a communications path (e.g., channel) 326. This path 326 carries signals 328 and may be implemented using wire or cable, fiber optics, a telephone line, a cellular link, an RF link and/or other communications channels. In this document, the terms “computer program medium” and “computer usable medium” are used to refer generally to media such as the removable storage unit 318, a hard disk installed in hard disk drive 312, and signals 328. These computer program products provide software to the computer system 300. Aspects of the present disclosures are directed to such computer program products.

Computer programs (also referred to as computer control logic) are stored in main memory 308 and/or secondary memory 310. Computer programs may also be received via communications circuit 324. Such computer programs, when executed, enable the computer system 300 to perform the features in accordance with aspects of the present disclosures, as discussed herein. In particular, the computer programs, when executed, enable the processor 304 to perform the features in accordance with aspects of the present disclosures. Accordingly, such computer programs represent controllers of the computer system 300.

In an aspect of the present disclosures where the method is implemented using software, the software may be stored in a computer program product and loaded into computer system 300 using removable storage drive 314, hard disk drive 312, or the interface 320. The control logic (software), when executed by the processor 304, causes the processor 304 to perform the functions described herein. In another aspect of the present disclosures, the system is implemented primarily in hardware using, for example, hardware components, such as application specific integrated circuits (ASICs). Implementation of the hardware state machine so as to perform the functions described herein will be apparent to persons skilled in the relevant art(s).

It will be appreciated that various implementations of the above-disclosed and other features and functions, or alternatives or varieties thereof, may be desirably combined into many other different systems or applications. Also that various presently unforeseen or unanticipated alternatives, modifications, variations, or improvements therein may be subsequently made by those skilled in the art which are also intended to be encompassed by the following claims.

What is claimed is:

1. A method by a magnetic signal receiver, comprising:
receiving a plurality of reception magnetic signals, wherein:
each one of the plurality of reception magnetic signals is based on at least a portion of a corresponding transmission magnetic signal of a plurality of transmission magnetic signals passing through a corresponding magnetic material of a plurality of magnetic materials associated with a plurality of markers of a security tag attached to a merchandize item,
each of the plurality of transmission magnetic signals is transmitted at a frequency of a plurality of frequencies,
each of the plurality of magnetic materials is configured to have a first absorption coefficient for a corresponding transmission magnetic signal of the plurality of transmission magnetic signals and a second absorption coefficient for the corresponding transmission magnetic signal of the plurality of transmission magnetic signals;
determining state information associated with each marker of the plurality of markers based on a corresponding transmission magnetic signal of the plurality of transmission magnetic signals and a corresponding reception magnetic signal of the plurality of reception magnetic signals; and
determining tag information based on the state information of the plurality of markers.

2. The method of claim 1, wherein the plurality of magnetic materials include nuclear quadrupole resonance (NQR) materials.

3. The method of claim 2, wherein the NQR materials include hydrogen, carbon, nitrogen, chlorine, potassium, bromine, rubidium, iodine, cesium, or lead.

4. The method of claim 1, wherein the tag information includes one or more of merchandize information, price, or purchase status associated with the merchandize item.

5. The method of claim 1, wherein the tag information indicates that the merchandize item has not been properly purchased.

6. The method of claim 5, further comprising transmitting an indication signal, in response to the tag information indicating that the merchandize item has not been properly purchased, to an alarm or security personnel.

7. The method of claim 1, further comprising determining, based on the plurality of reception magnetic signals, whether the security tag is within a threshold distance of a person.

8. The method of claim 7, wherein determining whether the security tag is within the threshold distance of a person comprises:
comparing a frequency response of the plurality of reception magnetic signals with a threshold frequency response associated with the security tag being disposed at a distance larger than the threshold distance from an object; and
determining that a deviation between the frequency response and the threshold frequency response is larger than a threshold deviation.

9. A magnetic signal receiver, comprising:
a memory,
an antenna configured to:
receive a plurality of reception magnetic signals, wherein:
each one of the plurality of reception magnetic signals is based on at least a portion of a corresponding transmission magnetic signal of a plurality of transmission magnetic signals passing through a corresponding magnetic material of a plurality of magnetic materials associated with a plurality of markers of a security tag attached to a merchandize item,
each one of the plurality of transmission magnetic signals is transmitted at a frequency of a plurality of frequencies,
each one of the plurality of magnetic materials is configured to have a first absorption coefficient for a corresponding transmission magnetic signal of the plurality of transmission magnetic signals and a second absorption coefficient for the corresponding transmission magnetic signal of the plurality of transmission magnetic signals; and
a processor operatively coupled to the memory and the antenna, the processor being configured to:
determine state information associated with each marker of the plurality of markers based on a corresponding transmission magnetic signal of the plurality of transmission magnetic signals and a corresponding reception magnetic signal of the plurality of reception magnetic signals; and
determine tag information based on the state information of the plurality of markers.

10. The magnetic signal receiver of claim 9, wherein the plurality of magnetic materials include nuclear quadrupole resonance (NQR) materials.

11. The magnetic signal receiver of claim 10, wherein the NQR materials include Hydrogen, Carbon, Nitrogen, Chlorine, Potassium, Bromine, Rubidium, Iodine, Cesium, or Lead.

12. The magnetic signal receiver of claim 9, wherein the tag information includes one or more of merchandize information, price, or purchase status associated with the merchandize item.

13. The magnetic signal receiver of claim 9, wherein the tag information indicates that the merchandize item has not been properly purchased.

14. The magnetic signal receiver of claim 9, wherein the antenna is further configured to transmit an indication signal, in response to the tag information indicating that the merchandize item has not been properly purchased, to an alarm or security personnel.

15. The magnetic signal receiver of claim 9, wherein the processor is further configured to determine, based on the plurality of reception magnetic signals, whether the security tag is within a threshold distance of a person.

16. The magnetic signal receiver of claim 15, wherein determining whether the security tag is within the threshold distance of a person comprises:
comparing a frequency response of the plurality of reception magnetic signals with a threshold frequency response associated with the security tag being disposed at a distance larger than the threshold distance from an object; and
determining that a deviation between the frequency response and the threshold frequency response is larger than a threshold deviation.

17. A security tag, comprising:
a plurality of markers of the security tag attached to a merchandize item, wherein:
each of the plurality of markers includes a corresponding magnetic material of a plurality of magnetic materials;
each of the plurality of magnetic materials includes a corresponding nuclear quadrupole resonance (NQR) frequency of a plurality of NQR frequencies;
each one of the plurality of magnetic materials is configured to have a first absorption coefficient for a corresponding transmission magnetic signal of a plurality of transmission magnetic signals and a second absorption coefficient for the corresponding transmission magnetic signal of the plurality of transmission magnetic signals; and
state information associated with the plurality of markers indicates tag information of the security tag.

18. The security tag of claim 17, wherein the plurality of magnetic materials include NQR materials.

19. The security tag of claim 18, wherein the NQR materials include Hydrogen, Carbon, Nitrogen, Chlorine, Potassium, Bromine, Rubidium, Iodine, Cesium, or Lead.

20. The security tag of claim 17, wherein the tag information includes one or more of merchandize information, price, or purchase status associated with the merchandize item.
